(19) United States
(12) Patent Application Publication
(10) Pub. No.: US 2023/0364716 A1
(43) Pub. Date: Nov. 16, 2023

(54) MANUFACTURING METHOD OF SUBSTRATE

(71) Applicant: DISCO CORPORATION, Tokyo (JP)

(72) Inventor: Hayato IGA, Tokyo (JP)

(21) Appl. No.: 18/304,676

(22) Filed: Apr. 21, 2023

(30) Foreign Application Priority Data
May 13, 2022 (JP) 2022-079703

(51) Int. Cl. B23K 26/53; B23K 26/046

(52) U.S. Cl. CPC B23K 26/53; B23K 26/046; B23K 2103/56

(57) ABSTRACT

A preliminary processing step of forming modified parts in an outer circumferential region of a workpiece is executed prior to a main processing step of forming modified parts and cracks in each of plural linear regions included in the workpiece. This can promote extension of the cracks in the outer circumferential region of the workpiece in the main processing step. As a result, splitting-off of a substrate from the workpiece in a splitting-off step becomes easy. In addition, the probability of occurrence of large chipping in the outer circumferential region of the workpiece in this splitting-off can be reduced.

### BACKGROUND OF THE INVENTION

### Field of the Invention

The present invention relates to a manufacturing method of a substrate by which the substrate is manufactured from a workpiece having a first surface and a second surface on the opposite side of the first surface.

### Description of the Related Art

Typically, chips of a semiconductor device are manufactured with use of a circular disc-shaped substrate composed of a semiconductor material such as single-crystal silicon or single-crystal silicon carbide. This substrate is cut out from an ingot with a circular column shape by a wire saw, for example (for example, refer to Japanese Patent Laid-open No. H09-262826).

However, the cutting allowance when the substrate is cut out from the ingot by the wire saw is approximately 300 μm, which is relatively large. Moreover, minute surface irregularities are formed in a surface of the substrate thus cut out, and this substrate bends in whole (warpage occurs in the substrate). Accordingly, when chips are manufactured with use of this substrate, the surface of the substrate needs to be planarized through execution of lapping, etching, and/or polishing for the surface.

In this case, the amount of semiconductor material finally used as the substrates is approximately ⅔ of the total amount of ingot. That is, approximately ⅓ of the total amount of ingot is discarded in the cutting-out of the substrates from the ingot and the planarization of surfaces of the substrates. Hence, the productivity becomes low in the case of manufacturing the substrates by the wire saw as described above.

In view of this point, there has been proposed a method in which a separation layer including modified parts and cracks that extend from the modified parts is formed inside an ingot by irradiation of the ingot with a laser beam with such a wavelength as to be transmitted through a semiconductor material from the front surface side and thereafter a substrate is split off from the ingot with use of this separation layer as the point of origin (for example, refer to Japanese Patent Laid-open No. 2022-25566). When a substrate is manufactured from an ingot by this method, the productivity of the substrate can be improved compared with the case in which the substrate is manufactured from the ingot by the wire saw.

### SUMMARY OF THE INVENTION

Typically, irradiation of an ingot with a laser beam is executed while the focal point on which the laser beam is focused and the ingot are moved relative to each other along a predetermined direction. Here, when an outer circumferential region of the ingot is irradiated with the laser beam, part (former) of the laser beam with which the ingot is irradiated is transmitted through a surface of the ingot whereas the remaining part (latter) thereof is not transmitted through the surface of the ingot in some cases.

In this case, the focal point on which the former is focused and the focal point on which the latter is focused deviate from each other due to difference in the refractive index between the internal and the external of the ingot. Moreover, the power of the laser beam focused in the internal of the ingot increases as the ratio of the former increases. That is, when the laser beam moves from the outside toward the inside with respect to the outer circumferential of the ingot, the power of the laser beam focused in the internal of the ingot gradually increases.

Thus, when the outer circumferential region of the ingot is irradiated with the laser beam, there is a possibility that the power of the laser beam is not stable and the modified parts and the cracks are not sufficiently formed. In addition, if the modified parts and the cracks are not sufficiently formed in the outer circumferential region of the ingot, there is a possibility that it becomes difficult to split off the outer circumferential region when a substrate is split off from the ingot.

Moreover, even if a substrate can be split off from the ingot, there is a possibility that large chipping occurs in the outer circumferential region of the ingot in the splitting-off. In this case, the amount of semiconductor material discarded in planarization of a surface of the substrate becomes large, and the productivity of the substrate lowers.

In view of this point, an object of the present invention is to provide a manufacturing method of a substrate that facilitates splitting-off of a substrate from a workpiece such as an ingot and can reduce the probability of the occurrence of large chipping in an outer circumferential region of the workpiece in the splitting-off.

In accordance with an aspect of the present invention, there is provided a manufacturing method of a substrate by which the substrate is manufactured from a workpiece having a first surface and a second surface on the opposite side of the first surface. The manufacturing method includes a separation layer forming step of forming a separation layer including modified parts and cracks that extend from the modified parts, inside the workpiece, by irradiating the workpiece with a laser beam with such a wavelength as to be transmitted through a material that configures the workpiece, from the side of the first surface and a splitting-off step of splitting off the substrate from the workpiece with use of the separation layer as a point of origin after the separation layer forming step is executed. The separation layer forming step includes a preliminary processing step of forming the modified parts in an outer circumferential region of the workpiece by moving focal points on which the laser beam is focused and the workpiece relative to each other in a state in which the focal points are positioned to the outer circumferential region and a main processing step of, after the preliminary processing step is executed, forming the modified parts and the cracks in each of multiple linear regions that each extend along a first direction and that are included in the workpiece, by repeating a laser beam irradiation step of moving the focal points and the workpiece relative to each other along the first direction in a state in which the focal points are positioned to any of the multiple linear regions and an indexing feed step of moving a position at which the focal points are formed and the workpiece relative to each other along a second direction that is orthogonal to the first direction and is parallel to the first surface.

Preferably, the focal points are positioned to a first depth from the first surface in the preliminary processing step, and the focal points are positioned to a second depth different from the first depth from the first surface in the laser beam irradiation step.

Moreover, preferably, the power of the laser beam focused on the focal points in the preliminary processing step is lower than the power of the laser beam focused on the focal points in the laser beam irradiation step.

Further, preferably, the workpiece is composed of single-crystal silicon manufactured in such a manner that a specific crystal plane included in crystal planes {100} is exposed in each of the first surface and the second surface, the first direction is parallel to the specific crystal plane, and an angle formed by the first direction and a specific crystal orientation included in crystal orientations <100> is equal to or smaller than 5°.

In the present invention, the preliminary processing step of forming the modified parts in the outer circumferential region of the workpiece is executed prior to the main processing step of forming the modified parts and the cracks in each of the multiple linear regions included in the workpiece.

This can promote extension of the cracks in the outer circumferential region of the workpiece in the main processing step. As a result, the splitting-off of the substrate from the workpiece in the splitting-off step becomes easy. In addition, the probability of occurrence of large chipping in the outer circumferential region of the workpiece in this splitting-off can be reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating one example of an ingot;

FIG. 2 is a top view schematically illustrating the one example of the ingot;

FIG. 3 is a flowchart schematically illustrating one example of a manufacturing method of a substrate by which the substrate is manufactured from the ingot that becomes a workpiece;

FIG. 4 is a flowchart schematically illustrating one example of a separation layer forming step illustrated in FIG. 3;

FIG. 5 is a diagram schematically illustrating one example of a laser processing apparatus used when a separation layer is formed inside the ingot;

FIG. 6 is a top view schematically illustrating the state in which the ingot is held at a holding table of the laser processing apparatus;

FIG. 7A is a perspective view schematically illustrating the state of a preliminary processing step illustrated in FIG. 4;

FIG. 7B is a sectional view schematically illustrating modified parts formed inside the ingot in the preliminary processing step illustrated in FIG. 4;

FIG. 8 is a top view schematically illustrating the ingot obtained after the preliminary processing step illustrated in FIG. 4;

FIG. 9 is a flowchart schematically illustrating one example of a main processing step illustrated in FIG. 4;

FIG. 10A is a perspective view schematically illustrating the state of a laser beam irradiation step illustrated in FIG. 9;

FIG. 10B is a sectional view schematically illustrating modified parts and cracks formed inside the ingot in the laser beam irradiation step illustrated in FIG. 9;

FIG. 11 is a top view schematically illustrating the ingot obtained after the separation layer forming step illustrated in FIG. 3;

FIG. 12A is a partially sectional side view schematically illustrating the state of a first stage of one example of a splitting-off step illustrated in FIG. 3;

FIG. 12B is a partially sectional side view schematically illustrating the state of a second stage of the one example of the splitting-off step illustrated in FIG. 3;

FIG. 13 is a graph illustrating the width of the separation layer formed inside a workpiece composed of single-crystal silicon when regions that are each along a different crystal orientation are irradiated with a laser beam;

FIG. 14A is a partially sectional side view schematically illustrating the state of a first stage of another example of the splitting-off step illustrated in FIG. 3; and

FIG. 14B is a partially sectional side view schematically illustrating the state of a second stage of the other example of the splitting-off step illustrated in FIG. 3.

### DETAILED DESCRIPTION OF THE PREFERRED EMBODIMENT

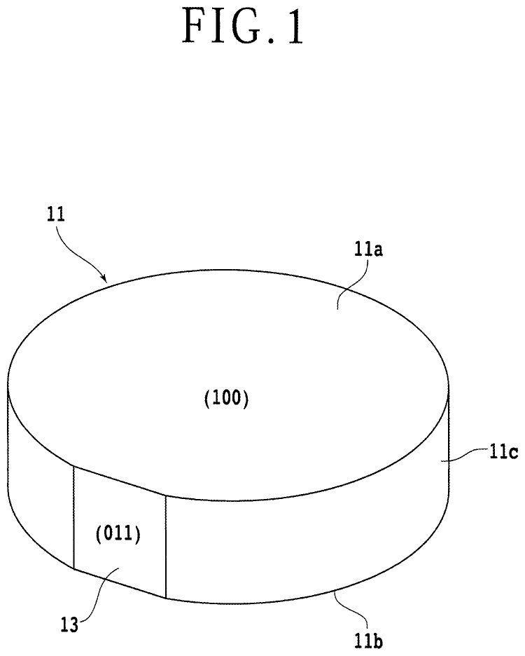

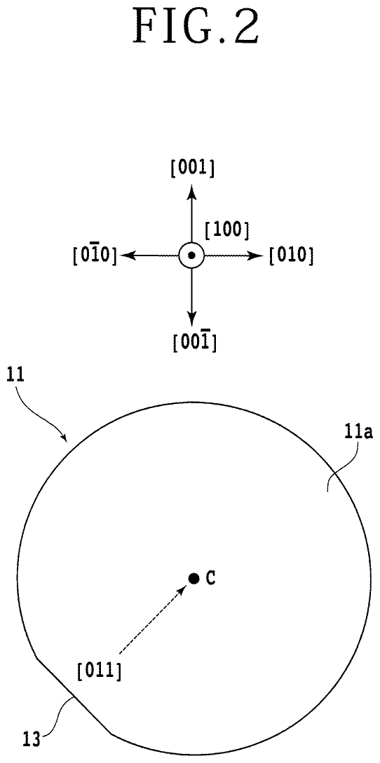

An embodiment of the present invention will be described with reference to the accompanying drawings. FIG. 1 is a perspective view schematically illustrating one example of a circular columnar ingot composed of single-crystal silicon. FIG. 2 is a top view schematically illustrating the one example of this ingot.

In FIG. 1, crystal planes of the single-crystal silicon exposed in planes included in this ingot are also illustrated. Moreover, in FIG. 2, crystal orientations of the single-crystal silicon that configures this ingot are also illustrated.

In an ingot 11 illustrated in FIG. 1 and FIG. 2, a specific crystal plane included in crystal planes {100} (here, defined as a crystal plane (100) for convenience) is exposed in each of a circular front surface (first surface) 11a and a circular back surface (second surface) 11b. That is, in the ingot 11, the perpendicular line (crystal axis) to each of the front surface 11a and the back surface 11b is along a crystal orientation [100].

In the ingot 11, although the ingot 11 is manufactured in such a manner that the crystal plane (100) is exposed in each of the front surface 11a and the back surface 11b, a surface slightly inclined from the crystal plane (100) may be exposed in each of the front surface 11a and the back surface 11b due to a processing error in the manufacturing, or the like.

Specifically, a surface regarding which the angle formed with respect to the crystal plane (100) is equal to or smaller than 1° may be exposed in each of the front surface 11a and the back surface 11b of the ingot 11. That is, the crystal axis of the ingot 11 may be along a direction regarding which the angle formed with respect to the crystal orientation [100] is equal to or smaller than 1°.

Moreover, an orientation flat 13 is formed in a side surface 11c of the ingot 11, and a center C of the ingot 11 is located in a specific crystal orientation included in crystal orientations <110> (here, defined as a crystal orientation [011] for convenience) as viewed from the orientation flat 13. That is, a crystal plane (011) of the single-crystal silicon is exposed in the orientation flat 13.

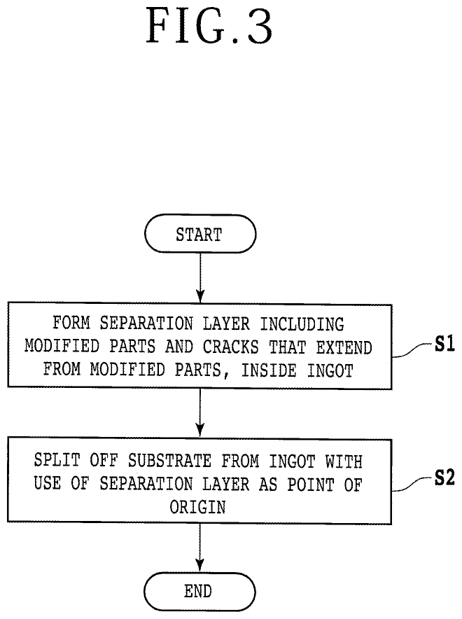

FIG. 3 is a flowchart schematically illustrating one example of a manufacturing method of a substrate by which the substrate is manufactured from the ingot 11 that becomes a workpiece. In this method, first, a separation layer including modified parts and cracks that extend from the modified parts is formed inside the ingot 11 (separation layer forming step: S1).

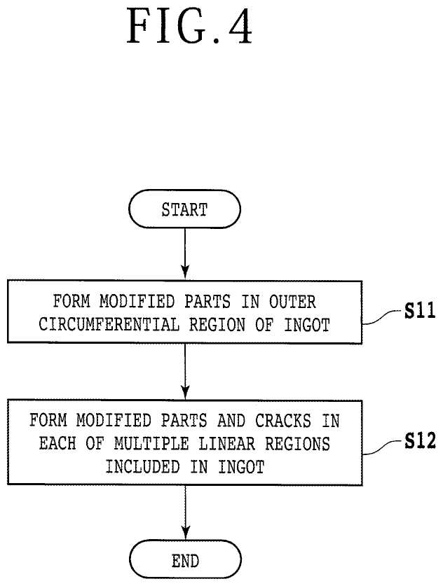

FIG. 4 is a flowchart schematically illustrating one example of the separation layer forming step (S1). In the separation layer forming step (S1), first, modified parts are formed in an outer circumferential region of the ingot 11 (preliminary processing step: S11). Then, after the preliminary processing step (S11) is executed, the modified parts and the cracks are formed in each of multiple linear regions included in the ingot 11 (main processing step: S12).

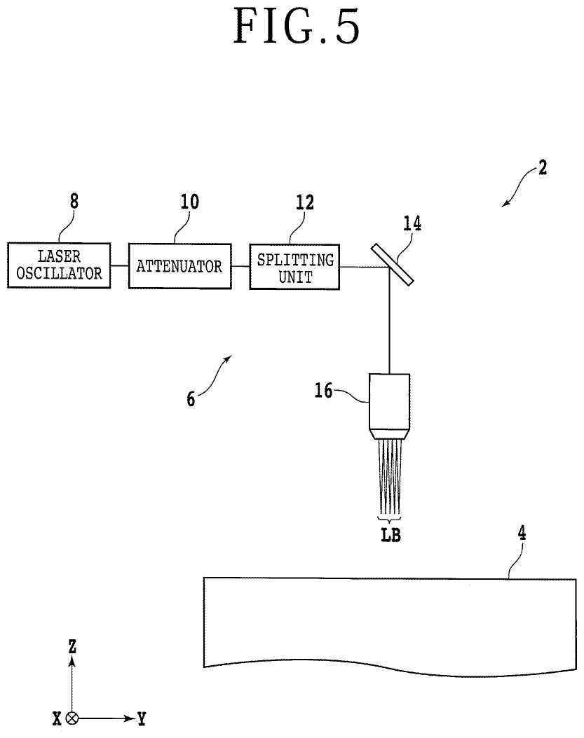

Moreover, in the separation layer forming step (S1), the separation layer is formed inside the ingot 11 with use of a laser processing apparatus. FIG. 5 is a diagram schematically illustrating one example of the laser processing apparatus used when the separation layer is formed inside the ingot 11.

An X-axis direction (first direction) and a Y-axis direction (second direction) illustrated in FIG. 5 are directions orthogonal to each other on the horizontal plane. Moreover, a Z-axis direction is a direction (vertical direction) orthogonal to each of the X-axis direction and the Y-axis direction. In addition, in FIG. 5, some of constituent elements of the laser processing apparatus are illustrated by functional blocks.

A laser processing apparatus 2 illustrated in FIG. 5 has a holding table 4 with a circular disc shape. The holding table 4 has a circular upper surface (holding surface) parallel to the X-axis direction and the Y-axis direction, for example. Moreover, the holding table 4 has a circular disc-shaped porous plate (not illustrated) having an upper surface exposed in this holding surface.

Further, this porous plate communicates with a suction source (not illustrated) through a flow path provided inside the holding table 4, and so forth. This suction source includes an ejector or the like, for example. Moreover, when this suction source operates, a suction force acts on a space in the vicinity of the holding surface of the holding table 4. This can hold the ingot 11 placed on the holding surface by the holding table 4, for example.

In addition, the holding table 4 is coupled to a rotational drive source (not illustrated). This rotational drive source includes a spindle, a motor, and so forth, for example. Moreover, when this rotational drive source operates, the holding table 4 rotates with a straight line that passes through the center of the holding surface and that is along the Z-axis direction being the rotation axis.

Moreover, a laser beam irradiation unit 6 is disposed over the holding table 4. The laser beam irradiation unit 6 has a laser oscillator 8. For example, the laser oscillator 8 has neodymium doped yttrium aluminum garnet (Nd:YAG) or the like as a laser medium and emits a pulsed laser beam LB with such a wavelength as to be transmitted through the material that configures the ingot 11 (single-crystal silicon).

This laser beam LB is supplied to a splitting unit 12 after its output power (power) is adjusted in an attenuator 10. For example, the splitting unit 12 has a spatial light modulator including a liquid crystal phase control element referred to as liquid crystal on silicon (LCoS) and/or a diffractive optical element (DOE), and so forth.

Further, the splitting unit 12 splits the laser beam LB in such a manner that the laser beam LB with which the holding surface side of the holding table 4 is irradiated from an irradiation head 16 to be described later forms multiple focal points that line up along the Y-axis direction.

The laser beam LB split in the splitting unit 12 is reflected by a mirror 14 and is guided to the irradiation head 16. A collecting lens (not illustrated) that focuses the laser beam LB and so forth are housed in the irradiation head 16. Moreover, the laser beam LB focused by this collecting lens is emitted toward the holding surface side of the holding table 4, to put it simply, directly downward, with a central region of the lower surface of the irradiation head 16 being an emission region.

Further, the irradiation head 16 of the laser beam irradiation unit 6 and an optical system (for example, a mirror 14) for guiding the laser beam LB to the irradiation head 16 are coupled to a movement mechanism (not illustrated). This movement mechanism includes a ball screw and so forth, for example. Moreover, when this movement mechanism operates, the emission region of the laser beam LB moves along the X-axis direction, the Y-axis direction, and/or the Z-axis direction.

Further, in the laser processing apparatus 2, the position (coordinates) in the X-axis direction, the Y-axis direction, and the Z-axis direction regarding the focal points on which the laser beam LB with which the holding surface side of the holding table 4 is irradiated from the irradiation head 16 is focused can be adjusted by operation of the rotational drive source that rotates the holding table 4 and/or the movement mechanism that moves the emission region of the laser beam LB.

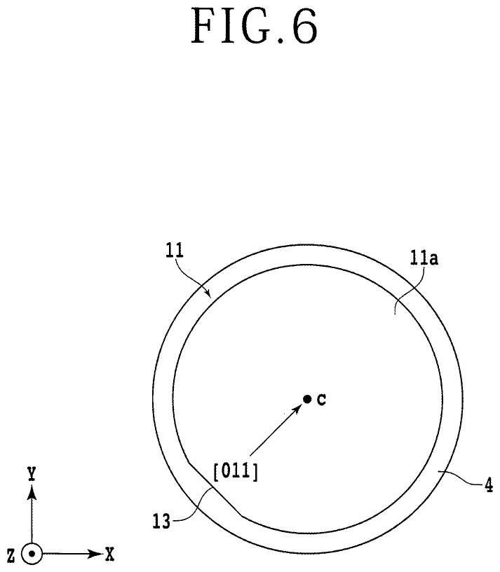

When the separation layer forming step (S1) is executed in the laser processing apparatus 2, first, the holding table 4 holds the ingot 11 in the state in which the front surface 11a is oriented upward. FIG. 6 is a top view schematically illustrating the state in which the ingot 11 is held at the holding table 4 of the laser processing apparatus 2.

For example, the ingot 11 is held by the holding table 4 in the state in which the angle formed by the direction from the orientation flat 13 toward the center C of the ingot 11 (crystal orientation [011]) with respect to each of the X-axis direction and the Y-axis direction is 45°.

That is, the ingot 11 is held by the holding table 4 in the state in which the crystal orientation [010] is parallel to the X-axis direction and the crystal orientation [001] is parallel to the Y-axis direction, for example. After the ingot 11 is held by the holding table 4 in this manner, the preliminary processing step (S11) illustrated in FIG. 4 is executed.

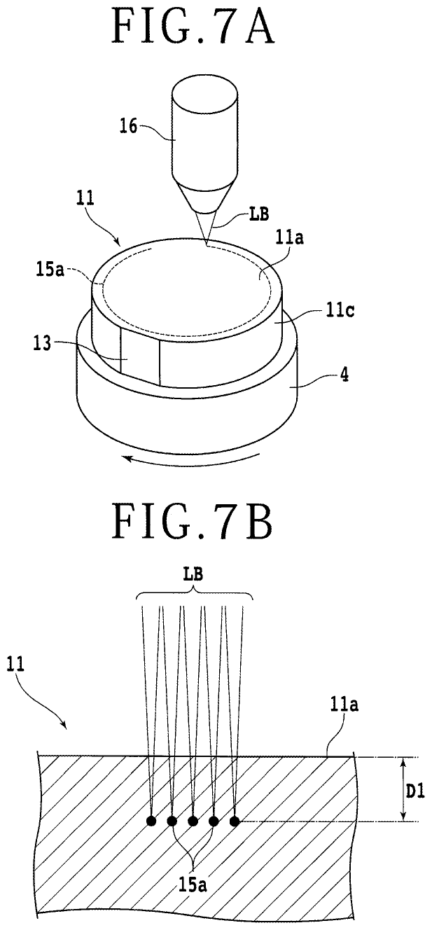

FIG. 7A is a perspective view schematically illustrating the state of one example of the preliminary processing step (S11). FIG. 7B is a sectional view schematically illustrating the modified parts formed inside the ingot 11 in the preliminary processing step (S11). The preliminary processing step (S11) is executed in the following order, for example.

Specifically, first, the emission region of the laser beam LB is positioned directly above the outer circumferential region of the ingot 11. The outer circumferential region of the ingot 11 is a region in the vicinity of the side surface 11c thereof. For example, the outer circumferential region of the ingot 11 is a region located, in plan view, between the side surface 11c of the ingot 11 and a circular cylindrical virtual plane separate inward from the side surface 11c by 0.5% to 3.0% of the diameter of the ingot 11.

Subsequently, the emission region of the laser beam LB is raised and lowered to cause the multiple focal points formed by focusing of the respective laser beams LB resulting from splitting to be positioned to a height corresponding to a first depth D1 from the front surface 11a of the ingot 11.

Next, the laser beam LB is emitted from the irradiation head 16 toward the ingot 11. The laser beam LB is split and focused to form multiple (for example, five) focal points that line up at equal intervals in the Y-axis direction, for example. At this time, the interval between the pair of adjacent focal points is set to, for example, at least 5 μm and at most 20 μm, typically 10 μm.

Moreover, the power of the laser beam LB focused on each of the multiple focal points, that is, the power obtained by dividing the power of the laser beam LB adjusted in the attenuator 10 by the number of split laser beams (for example, five), is relatively low and is set to, for example, at least 0.1 W and at most 0.3 W, typically 0.2 W.

As a result, a modified part 15a arising from disordering of the crystal structure of the single-crystal silicon is formed in the outer circumferential region of the ingot 11, with each of the multiple focal points being the center of the modified part 15a. In addition, when the modified parts 15a are formed in this manner, the volume of the ingot 11 expands, and an internal stress is generated in the ingot 11.

Moreover, when this internal stress becomes high, cracks extend from the modified parts 15a to alleviate the internal stress in some cases. However, it is preferable that the power of the laser beam LB focused on each of the multiple focal points be adjusted in such a manner that the modified parts 15a are formed but cracks do not extend from the modified parts 15a, in the preliminary processing step (S11).

Subsequently, one revolution of the holding table 4 is made with the irradiation of the ingot 11 with the laser beam LB from the irradiation head 16 being kept. This forms the modified part 15a that extends in a circular annular manner (more specifically, multiple (for example, five) modified parts 15a that concentrically extend) in the outer circumferential region of the ingot 11.

Further, in the preliminary processing step (S11), other modified parts 15a may be formed in the outer circumferential region of the ingot 11 through execution of the above-described operation again after the center of the emission region of the laser beam LB is caused to get closer to or farther away from the center C of the ingot 11 in plan view. This can form the modified parts 15a across a wide range in the outer circumferential region of the ingot 11.

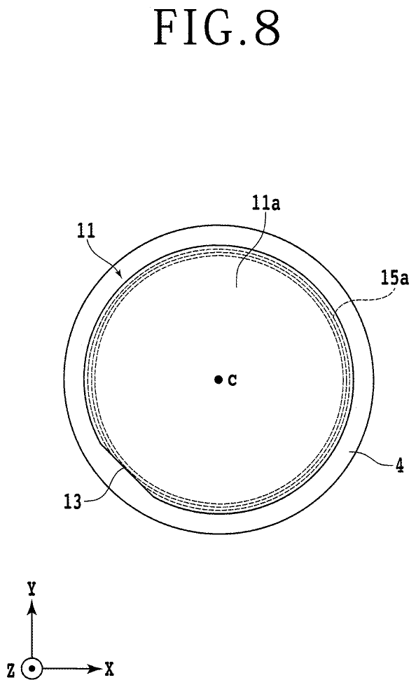

FIG. 8 is a top view schematically illustrating the ingot 11 obtained after the preliminary processing step (S11) in which the above-described operation is executed three times. When the preliminary processing step (S11) is executed in this manner, the width (length along the radial direction of the ingot 11) of the modified parts 15a formed in a region near the orientation flat 13 is smaller than the width of the modified parts 15a formed in the other region in some cases.

In light of this point, in the preliminary processing step (S11), the region near the orientation flat 13 may be irradiated with the laser beam LB in the state in which the center of the emission region of the laser beam LB is brought closer to the center C of the ingot 11 in plan view. This can form the modified parts 15a having an equivalent width in the region near the orientation flat 13 and the other region.

After the preliminary processing step (S11) is completed, the main processing step (S12) illustrated in FIG. 4 is executed. The holding table 4 may be rotated prior to the main processing step (S12) if the rotation is necessary to dispose the ingot 11 in a predetermined orientation. For example, the holding table 4 that holds the ingot 11 may be rotated to cause the crystal orientation [010] to become parallel to the X-axis direction and cause the crystal orientation [001] to become parallel to the Y-axis direction.

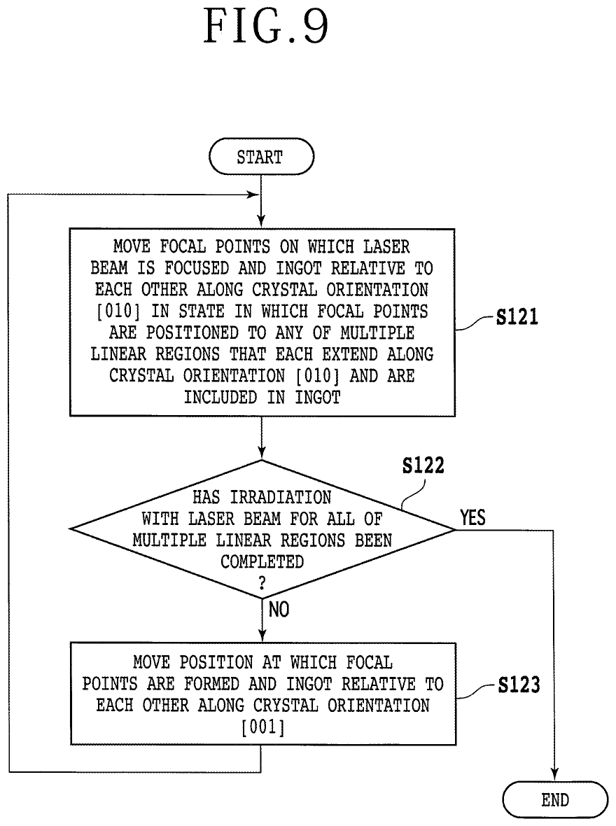

FIG. 9 is a flowchart schematically illustrating one example of the main processing step (S12). In the main processing step (S12), first, the focal points on which the laser beam LB is focused and the ingot 11 are moved relative to each other along the crystal orientation [010] in the state in which the focal points are positioned to any of the multiple linear regions that each extend along the crystal orientation [010] and that are included in the ingot 11 (laser beam irradiation step: S121).

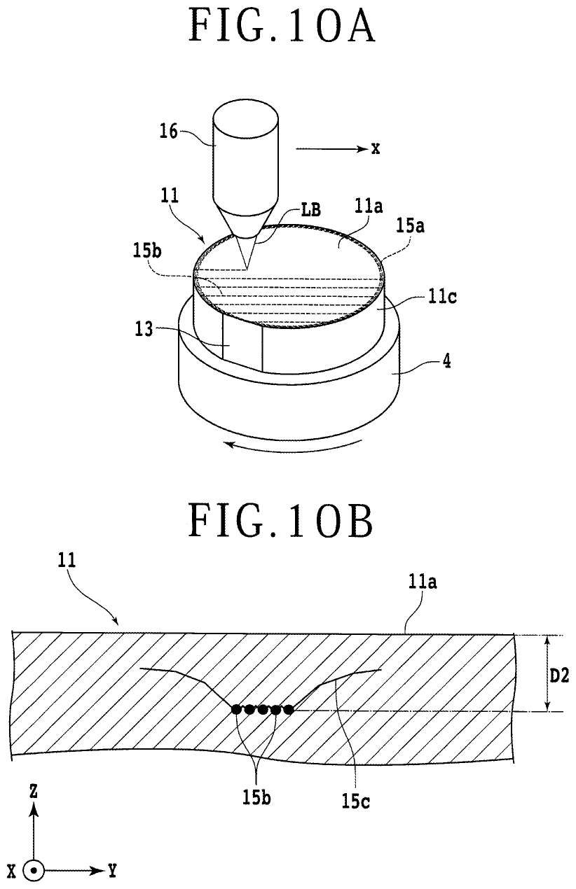

FIG. 10A is a perspective view schematically illustrating the state of one example of the laser beam irradiation step (S121). FIG. 10B is a sectional view schematically illustrating modified parts and cracks formed inside the ingot 11 in the laser beam irradiation step (S121). The laser beam irradiation step (S121) is executed in the following order, for example.

Specifically, first, the emission region of the laser beam LB is positioned in such a manner that, in plan view, a region located at one end in the Y-axis direction (crystal orientation [001]) that is among the multiple linear regions included in the ingot 11 is positioned in the X-axis direction (crystal orientation) [010]) as viewed from the emission region of the laser beam LB.

Subsequently, the emission region of the laser beam LB is raised and lowered to cause the multiple focal points formed by focusing the respective laser beams LB resulting from splitting to be positioned to a height corresponding to a second depth D2 from the front surface 11a of the ingot 11.

The second depth D2 is a depth different from the above-described first depth D1 and, for example, is deeper than the first depth D1. For example, the difference between the first depth D1 and the second depth D2 is larger than 0 μm but is at most 120 μm.

Next, while the ingot 11 is irradiated with the laser beam LB from the irradiation head 16, the emission region of the laser beam LB is moved to pass from one end to the other end of the ingot 11 in the X-axis direction (crystal orientation [010]) in plan view.

When the emission region of the laser beam LB moves with the irradiation with the laser beam LB in this manner, the multiple focal points and the ingot 11 relatively move along the X-axis direction (crystal orientation [010]) in the state in which the multiple focal points are positioned to the second depth D2 from the front surface 11a of the ingot 11.

The laser beam LB is split and focused to form multiple (for example, five) focal points that line up at equal intervals in the Y-axis direction (crystal orientation [001]). At this time, the interval between the pair of adjacent focal points is set to, for example, at least 5 μm and at most 20 μm, typically 10 μm.

Moreover, in the laser beam irradiation step (S121), the power of the laser beam LB focused on each of the multiple focal points is set to be higher than the power in the preliminary processing step (S11). For example, the power of the laser beam LB focused on each of the multiple focal points in the laser beam irradiation step (S121) is set to at least 0.3 W and at most 0.6 W, preferably at least 0.35 W and at most 0.5 W.

As a result, in the region located at the one end in the Y-axis direction (crystal orientation) [001]) that is among the multiple linear regions included in the ingot 11, a modified part 15b arising from disordering of the crystal structure of the single-crystal silicon is formed with each of the multiple focal points being the center of the modified part 15b.

Moreover, when the modified parts 15b are formed in this region, the volume of the ingot 11 expands, and an internal stress is generated in the ingot 11. In addition, in this region, cracks 15c extend from the modified parts 15b to alleviate this internal stress.

The cracks 15c that extend from the modified parts 15b are liable to extend to go toward the modified parts 15a already formed in the outer circumferential region of the ingot 11 and traverse the modified parts 15a.

Further, in the situation in which irradiation with the laser beam LB for all of the multiple linear regions included in the ingot 11 has not been completed (step (S122): NO), the position at which the focal points are formed and the ingot 11 are moved relative to each other along the Y-axis direction (crystal orientation [001]) (indexing feed step: S123).

Specifically, in the indexing feed step (S123), the emission region of the laser beam LB is moved along the Y-axis direction (crystal orientation [001]) by at least 300 μm and at most 750 μm, typically 550 μm, for example.

Next, the above-described laser beam irradiation step (S121) is executed again. Further, the indexing feed step (S123) and the laser beam irradiation step (S121) are alternately executed repeatedly until the modified parts 15b and the cracks 15c are formed in all of the multiple linear regions included in the ingot 11.

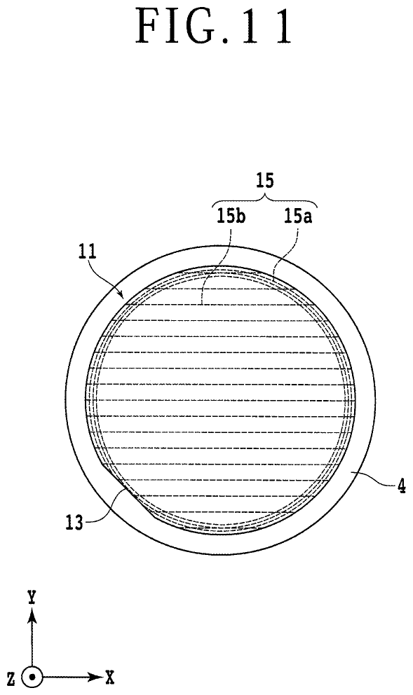

Subsequently, when the modified parts 15b and the cracks 15c have been formed in all of the multiple linear regions included in the ingot 11 (step (S122): YES), the main processing step (S12) illustrated in FIG. 4 is completed. FIG. 11 is a top view schematically illustrating the ingot 11 obtained after the main processing step (S12), that is, the ingot 11 obtained after the separation layer forming step (S1) illustrated in FIG. 3.

When the separation layer forming step (S1) has been executed as described above, a separation layer 15 including the modified parts 15a that are formed in the outer circumferential region of the ingot 11 and have a circular annular shape, the modified parts 15b formed in each of the multiple linear regions included in the ingot 11, and the cracks 15c (not illustrated in FIG. 11) that extend from the modified parts 15a and 15b is formed inside the ingot 11.

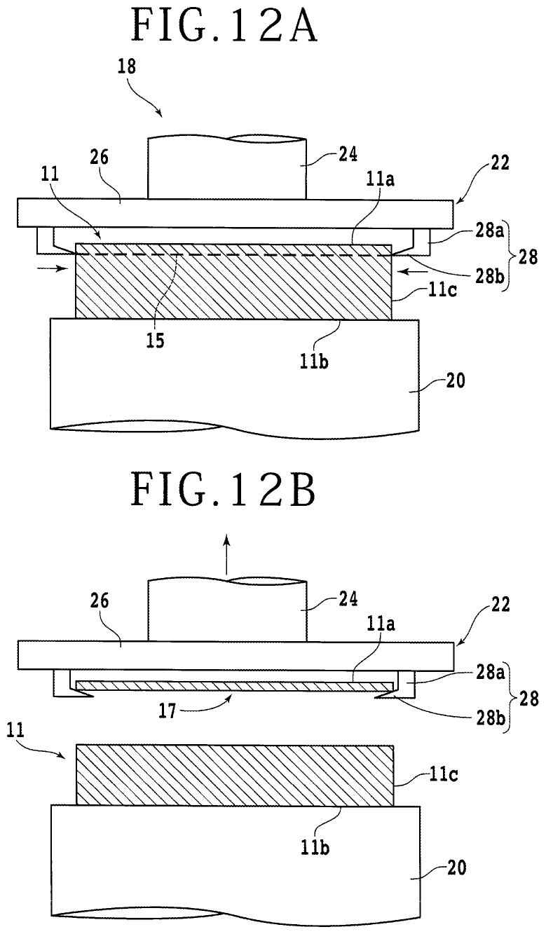

Subsequently, a substrate is split off from the ingot 11 with use of the separation layer 15 as the point of origin (splitting-off step: S2). Each of FIG. 12A and FIG. 12B is a partially sectional side view schematically illustrating the state of one example of the splitting-off step (S2). For example, the splitting-off step (S2) is executed in a splitting-off apparatus 18 illustrated in FIG. 12A and FIG. 12B.

The splitting-off apparatus 18 has a holding table 20 that holds the ingot 11 in which the separation layer 15 has been formed. The holding table 20 has a circular upper surface (holding surface), and a porous plate (not illustrated) is exposed in this holding surface.

Moreover, this porous plate communicates with a suction source (not illustrated) such as a vacuum pump through a flow path provided inside the holding table 20, and so forth. Further, when this suction source operates, a suction force acts on a space in the vicinity of the holding surface of the holding table 20. This can hold the ingot 11 placed on the holding surface by the holding table 20, for example.

Moreover, a splitting-off unit 22 is disposed over the holding table 20. The splitting-off unit 22 has a support member 24 with a circular column shape. To an upper part of the support member 24, a raising-lowering mechanism (not illustrated) of a ball screw system and a rotational drive source such as a motor are coupled, for example.

Further, the splitting-off unit 22 rises and lowers by operation of this raising-lowering mechanism. In addition, by operation of this rotational drive source, the support member 24 rotates with a straight line that passes through the center of the support member 24 and that is along the direction perpendicular to the holding surface of the holding table 20 being the rotation axis.

Moreover, a lower end part of the support member 24 is fixed to the center of an upper part of a base 26 with a circular disc shape. Further, on the lower side of an outer circumferential region of the base 26, multiple movable members 28 are disposed at substantially equal intervals along the circumferential direction of the base 26. The movable members 28 each have a plate-shaped erected part 28a that extends downward from the lower surface of the base 26.

Upper end parts of the erected parts 28a are coupled to an actuator such as an air cylinder incorporated in the base 26, and the movable members 28 move along the radial direction of the base 26 by operation of this actuator. Further, plate-shaped wedge parts 28b that extend toward the center of the base 26 and in which the thickness becomes thinner toward the tip are disposed on the inner side surfaces of lower end parts of the erected parts 28a.

In the splitting-off apparatus 18, the splitting-off step (S2) is executed in the following order, for example. Specifically, first, the ingot 11 is placed on the holding table 20 in such a manner that the center of the back surface 11b of the ingot 11 in which the separation layer 15 has been formed is made to correspond with the center of the holding surface of the holding table 20.

Subsequently, the suction source communicating with the porous plate exposed in this holding surface is operated to cause the ingot 11 to be held by the holding table 20. Next, the actuator is operated to position each of the multiple movable members 28 to the outside in the radial direction of the base 26.

Then, the raising-lowering mechanism is operated to position the tip of the wedge part 28b of each of the multiple movable members 28 to a height corresponding to the separation layer 15 formed inside the ingot 11. Next, the actuator is operated to cause the wedge parts 28b to be driven into the side surface 11c of the ingot 11 (see FIG. 12A).

Subsequently, the rotational drive source is operated to rotate the wedge parts 28b driven into the side surface 11c of the ingot 11. Next, the raising-lowering mechanism is operated to raise the wedge parts 28b (see FIG. 12B).

By raising the wedge parts 28b after driving the wedge parts 28b into the side surface 11c of the ingot 11 and rotating them as described above, the cracks 15c included in the separation layer 15 further extend. As a result, the side of the front surface 11a and the side of the back surface 11b of the ingot 11 are split off. That is, a substrate 17 is manufactured from the ingot 11 with use of the separation layer 15 as the point of origin.

The wedge parts 28b do not need to be rotated in a case where the side of the front surface 11a and the side of the back surface 11b of the ingot 11 are split off at the timing when the wedge parts 28b are driven into the side surface 11c of the ingot 11. Further, the wedge parts 28b that rotate may be driven into the side surface 11c of the ingot 11 through simultaneous operation of the actuator and the rotational drive source.

In the above-described manufacturing method of a substrate, the preliminary processing step (S11) of forming the modified parts 15a in the outer circumferential region of the ingot 11 is executed prior to the main processing step (S12) of forming the modified parts 15b and the cracks 15c in each of the multiple linear regions included in the ingot 11.

This can promote extension of the cracks 15c in the outer circumferential region of the ingot 11 in the main processing step (S12). As a result, the splitting-off of the substrate 17 from the ingot 11 in the splitting-off step (S2) becomes easy. In addition, the probability of the occurrence of large chipping in the outer circumferential region of the ingot 11 in this splitting-off can be reduced.

Moreover, according to the above-described manufacturing method of a substrate, in the main processing step (S12), the separation layer 15 is formed by moving the multiple focal points of the laser beam LB resulting from splitting and the ingot 11 relative to each other along the crystal orientation [010] in the state in which the focal points are positioned to the linear region extending along the crystal orientation.

In this case, the amount of material discarded when the substrate 17 is manufactured from the ingot 11 can be further reduced, and the productivity of the substrate 17 can be further improved. This point will be described in detail below. First, typically, the single-crystal silicon is cleaved along a specific crystal plane included in crystal planes {111} most easily and is cleaved along a specific crystal plane included in crystal planes {110} second most easily.

Thus, for example, when the modified part is formed along a specific crystal orientation included in crystal orientations <110> (for example, crystal orientation [011]) of the single-crystal silicon that configures the ingot 11, there occur many cracks that extend along the specific crystal plane included in the crystal planes {111} from this modified part.

On the other hand, when multiple modified parts are formed in a region along a specific crystal orientation included in crystal orientations <100> of the single-crystal silicon in such a manner as to line up along the direction orthogonal to the direction in which this region extends in plan view, there occur many cracks that extend along crystal planes that are parallel to the direction in which the region extends and that are among crystal planes {N10} (N is a natural number equal to or smaller than 10) from each of these multiple modified parts.

For example, when multiple modified parts 15b are formed in a region along the crystal orientation [010] in such a manner as to line up along the crystal orientation [001] as in the above-described manufacturing method of a substrate, there occur many cracks 15c that extend along crystal planes that are parallel to the crystal orientation [010] and that are among the crystal planes {N10} from each of these multiple modified parts 15b.

Specifically, when the multiple modified parts 15b are formed as described above, the cracks 15c easily extend in crystal planes illustrated by the following (1) and (2).

$$[ Math . 1 ]$$

$$( 101 ) , ( 201 ) , ( 301 ) , ( 401 ) , ( 501 ) , ( 601 ) , ( 701 ) , ( 801 ) , ( 901 ) , ( \underline{10} 01 ) \qquad ( 1 )$$

$$[ Math . 2 ]$$

$$( \overline{1} 01 ) , ( \overline{2} 01 ) , ( \overline{3} 01 ) , ( \overline{4} 01 ) , ( \overline{5} 01 ) , ( \overline{6} 01 ) , ( \overline{7} 01 ) , ( \overline{8} 01 ) , ( \overline{9} 01 ) , ( \overline{\underline{10}} 01 ) \qquad ( 2 )$$

Further, the angles formed by the crystal plane (100) exposed in the front surface 11a and the back surface 11b of the ingot 11 with respect to crystal planes that are parallel to the crystal orientation [010] and that are among the crystal planes {N10} are equal to or smaller than 45°. On the other hand, the angle formed by the crystal plane (100) with respect to a specific crystal plane included in the crystal planes {111} is approximately 54.7°.

Thus, in the above-described manufacturing method of a substrate, the separation layer 15 tends to have a wide width and be thin compared with the case in which multiple modified parts are formed in a region along the crystal orientation [011] of the single-crystal silicon in such a manner as to line up along the direction orthogonal to the direction in which this region extends in plan view. As a result, in the above-described manufacturing method of a substrate, the amount of material discarded when the substrate 17 is manufactured from the ingot 11 can be reduced, and the productivity of the substrate 17 can be improved.

The above-described contents are one aspect of the present invention, and the present invention is not limited to the above-described contents. For example, the structure of the laser processing apparatus used in the present invention is not limited to the structure of the above-described laser processing apparatus 2.

For example, the present invention may be carried out by a laser processing apparatus including a movement mechanism that moves the holding table 4 along each of the X-axis direction, the Y-axis direction, and/or the Z-axis direction.

That is, in the present invention, it suffices that the holding table 4 that holds the ingot 11 and the emission region of the laser beam LB can move relative to each other along each of the X-axis direction, the Y-axis direction, and the Z-axis direction, and there is no limitation on the structure for this purpose.

Moreover, in the preliminary processing step (S11) of the present invention, the modified part 15a that extends to become a shape other than the circular annular shape may be formed in the outer circumferential region of the ingot 11. For example, in the preliminary processing step (S11) of the present invention, the modified part 15a that extends in a spiral or straight line manner may be formed in the outer circumferential region of the ingot 11.

In the formation of the modified part 15a that extends in a spiral manner in the outer circumferential region of the ingot 11, for example, while the ingot 11 is irradiated with the laser beam LB from the irradiation head 16, the center of the emission region of the laser beam LB is caused to get closer to or farther away from the center C of the ingot 11 in plan view, in addition to the holding table 4 being rotated.

Further, in the formation of the modified part 15a that extends in a straight line manner in the outer circumferential region of the ingot 11, for example, the ingot 11 is intermittently irradiated with the laser beam LB from the irradiation head 16 while the emission region of the laser beam LB is moved similarly as in the above-described main processing step (S12).

That is, in this case, the irradiation with the laser beam LB from the irradiation head 16 is executed at timings when the emission region of the laser beam LB is located directly above the outer circumferential region of the ingot 11, and is stopped at timings when the emission region of the laser beam LB is located directly above the region surrounded by this outer circumferential region (central region).

Moreover, in the main processing step (S12) of the present invention, only the central region of the ingot 11 may be irradiated with the laser beam LB without the outer circumferential region of the ingot 11 being irradiated with the laser beam LB.

In this case, the irradiation with the laser beam LB from the irradiation head 16 is executed at timings when the emission region of the laser beam LB is located directly above the central region of the ingot 11, and is stopped at timings when the emission region of the laser beam LB is located directly above the outer circumferential region thereof.

Alternatively, in the main processing step (S12) of the present invention, without part of the outer circumferential region of the ingot 11 being irradiated with the laser beam LB, only the remaining part of the outer circumferential region of the ingot 11 and the central region of the ingot 11 may be irradiated with the laser beam LB.

In this case, for example, the irradiation with the laser beam LB from the irradiation head 16 is started when the emission region of the laser beam LB is moving directly above the outer circumferential region of the ingot 11 toward a position directly above the central region of the ingot 11, and is stopped when the emission region of the laser beam LB is moving directly above the outer circumferential region of the ingot 11 toward the outside of the ingot 11.

In the main processing step (S12), it is preferable to irradiate not only the central region of the ingot 11 but also at least part of the outer circumferential region of the ingot 11 with the laser beam LB. This causes the cracks 15c formed in the main processing step (S12) to easily extend to traverse the modified parts 15a formed in the preliminary processing step (S11).

Further, in the main processing step (S12) of the present invention, after each of the multiple linear regions included in the ingot 11 is irradiated with the laser beam LB, each of the multiple linear regions may be irradiated with the laser beam LB again. Alternatively, in the main processing step (S12) of the present invention, after the laser beam irradiation step (S121) but before the indexing feed step (S123), the laser beam irradiation step (S121) may be executed again.

That is, in the main processing step (S12) of the present invention, irradiation with the laser beam LB for forming the modified parts 15b and the cracks 15c may be executed again for the region in which the modified parts 15b and the cracks 15c have already been formed. This can increase the density of the modified parts 15b in each region and/or further extend the cracks 15c formed in each region.

In the case in which each of the multiple linear regions included in the ingot 11 is irradiated with the laser beam LB multiple times, the irradiation conditions of the laser beam LB in the respective rounds may be the same or be different. For example, in the second round of the irradiation of each region with the laser beam LB, the power of the laser beam LB focused on the focal points is adjusted to become higher than the power in the first round.

Moreover, the multiple linear regions included in the ingot 11 irradiated with the laser beam LB in the laser beam irradiation step (S121) of the present invention are not limited to regions along the crystal orientation [010]. For example, in the present invention, regions along the crystal orientation [001] may be irradiated with the laser beam LB.

When the ingot 11 is irradiated with the laser beam LB as described above, the cracks 15c easily extend in crystal planes illustrated by the following (3) and (4).

[Math. 3]

(110),(210),(310),(410),(510),(610),(710),(810),(910),(1010) (3)

[Math. 4]

(1̅10),(2̅10),(3̅10),(4̅10),(5̅10),(6̅10),(7̅10),(8̅10),(9̅10),(1̅0̅10) (4)

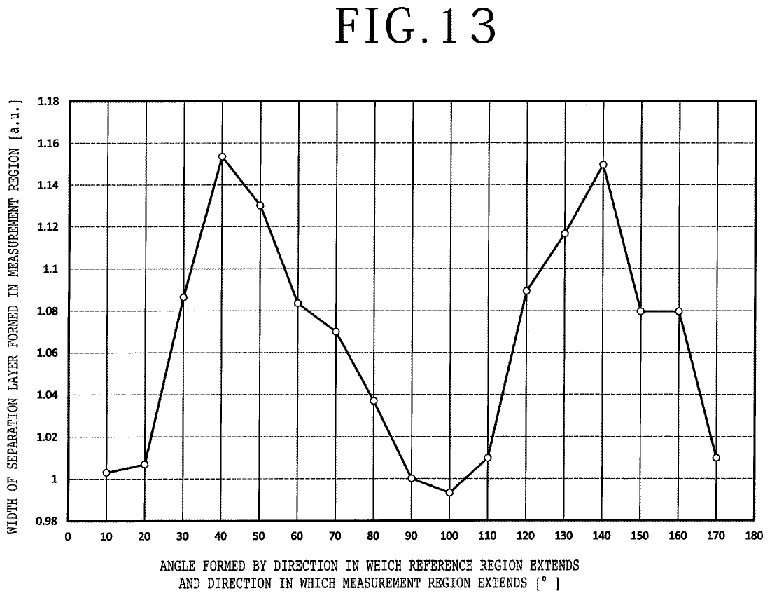

Moreover, in the present invention, a region along a direction slightly inclined from the crystal orientation [010] or the crystal orientation [001] in plan view may be irradiated with the laser beam LB. Regarding this point, description will be made with reference to FIG. 13.

FIG. 13 is a graph illustrating the width of the separation layer formed inside a workpiece composed of single-crystal silicon when regions that are each along a different crystal orientation are irradiated with the laser beam LB. The abscissa axis of this graph indicates the angle formed by the direction in which a region orthogonal to the crystal orientation [011] (reference region) extends and the direction in which a region that becomes a measurement subject (measurement region) extends in plan view.

That is, when the value of the abscissa axis of this graph is 45°, the region along the crystal orientation [001] is the measurement subject. Similarly, when the value of the abscissa axis of this graph is 135°, the region along the crystal orientation [010] is the measurement subject.

Further, the ordinate axis of this graph indicates the value obtained when the width of the separation layer formed in the measurement region by irradiation of the measurement region with the laser beam LB is divided by the width of the separation layer formed in the reference region by irradiation of the reference region with the laser beam LB.

As illustrated in FIG. 13, the width of the separation layer becomes wide when the angle formed by the direction in which the reference region extends and the direction in which the measurement region extends is at least 40° and at most 50° or at least 130° and at most 140°. That is, the width of the separation layer becomes wide not only when the region along the crystal orientation [001] or the crystal orientation [010] is irradiated with the laser beam LB but also when the region along a direction regarding which the angle formed with respect to either of these crystal orientations is equal to or smaller than 5° is irradiated with the laser beam LB.

Hence, in the laser beam irradiation step (S121) of the present invention, the region along a direction inclined from the crystal orientation [001] or the crystal orientation [010] by at most 5° in plan view may be irradiated with the laser beam LB.

That is, in the laser beam irradiation step (S121) of the present invention, irradiation with the laser beam LB may be executed for the region along a direction (first direction) that is parallel to the crystal plane which is exposed in each of the front surface 11a and the back surface 11b of the ingot 11 (here, crystal plane (100)) which is among specific crystal planes included in the crystal planes {100} and regarding which the angle formed with respect to a specific crystal orientation (here, crystal orientation [001] or crystal orientation [010]) included in the crystal orientations <100> is equal to or smaller than 5°.

Moreover, in the laser beam irradiation step (S121) of the present invention, the focal points on which the laser beam LB is focused and the ingot 11 may be moved relative to each other in the state in which the focal points are positioned to a depth shallower than the first depth.

Moreover, the splitting-off step (S2) of the present invention may be executed by an apparatus other than the splitting-off apparatus 18 illustrated in FIG. 12A and FIG. 12B. For example, in the splitting-off step (S2) of the present invention, the substrate 17 may be split off from the ingot 11 by the side of the front surface 11a of the ingot 11 being sucked.

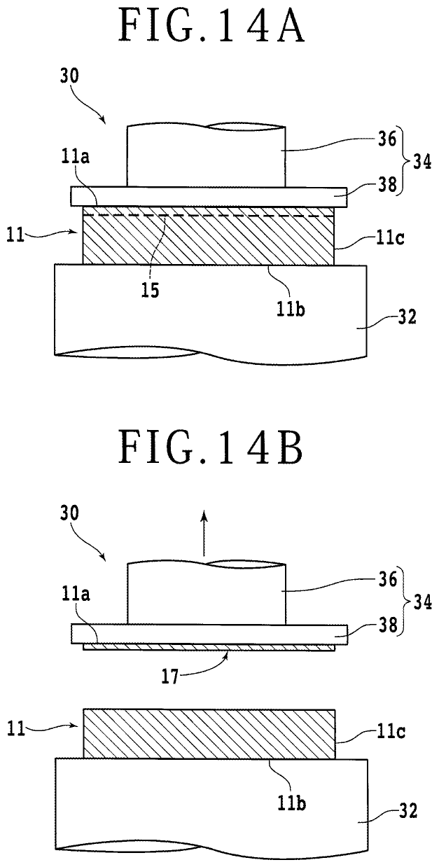

Each of FIG. 14A and FIG. 14B is a partially sectional side view schematically illustrating the state of the splitting-off step (S2) executed in this manner. A splitting-off apparatus 30 illustrated in FIG. 14A and FIG. 14B has a holding table 32 that holds the ingot 11 in which the separation layer 15 has been formed.

The holding table 32 has a circular upper surface (holding surface), and a porous plate (not illustrated) is exposed in this holding surface. Moreover, this porous plate communicates with a suction source (not illustrated) such as a vacuum pump through a flow path provided inside the holding table 32, and so forth.

Thus, when this suction source operates, a suction force acts on a space in the vicinity of the holding surface of the holding table 32. This can hold the ingot 11 placed on the holding surface by the holding table 32, for example.

Moreover, a splitting-off unit 34 is disposed over the holding table 32. The splitting-off unit 34 has a support member 36 with a circular column shape. To an upper part of the support member 36, a raising-lowering mechanism (not illustrated) of a ball screw system is coupled, for example. The splitting-off unit 34 rises and lowers by operation of this raising-lowering mechanism.

Further, a lower end part of the support member 36 is fixed to the center of an upper part of a suction plate 38 with a circular disc shape. Further, multiple suction ports are formed in the lower surface of the suction plate 38, and each of the multiple suction ports communicates with a suction source (not illustrated) such as a vacuum pump through a flow path provided inside the suction plate 38, and so forth.

Thus, when this suction source operates, a suction force acts on a space in the vicinity of the lower surface of the suction plate 38. This can suck the ingot 11 whose front surface 11a is close to the lower surface of the suction plate 38, in such a manner as to pull the ingot 11 upward, for example.

In the splitting-off apparatus 30, the splitting-off step (S2) is executed in the following order, for example. Specifically, first, the ingot 11 is placed on the holding table 32 in such a manner that the center of the back surface 11b of the ingot 11 in which the separation layer 15 has been formed is made to correspond with the center of the holding surface of the holding table 32.

Next, the suction source communicating with the porous plate exposed in this holding surface is operated to cause the ingot 11 to be held by the holding table 32. Subsequently, the raising-lowering mechanism is operated and the splitting-off unit 34 is lowered to bring the lower surface of the suction plate 38 into contact with the front surface 11a of the ingot 11.

Then, the suction source communicating with the multiple suction ports formed in the suction plate 38 is operated to cause the side of the front surface 11a of the ingot 11 to be sucked through the multiple suction ports (see FIG. 14A). Next, the raising-lowering mechanism is operated and the splitting-off unit 34 is raised to separate the suction plate 38 from the holding table 32 (see FIG. 14B).

At this time, an upward force acts on the side of the front surface 11a of the ingot 11 that is sucked through the multiple suction ports formed in the suction plate 38. As a result, the cracks 15c included in the separation layer 15 further extend, and the side of the front surface 11a and the side of the back surface 11b of the ingot 11 are split off. That is, the substrate 17 is manufactured from the ingot 11 with use of the separation layer 15 as the point of origin.

Further, in the splitting-off step (S2) of the present invention, ultrasonic waves may be given to the side of the front surface 11a of the ingot 11 prior to the splitting-off between the side of the front surface 11a and the side of the back surface 11b of the ingot 11. In this case, the cracks 15c included in the separation layer 15 further extend, making the splitting-off between the side of the front surface 11a and the side of the back surface 11b of the ingot 11 easy.

Moreover, in the present invention, the front surface 11a of the ingot 11 may be planarized by grinding or polishing (planarization step) prior to the separation layer forming step (S1). For example, this planarization may be executed when multiple substrates are manufactured from the ingot 11.

Specifically, when splitting-off in the ingot 11 is caused at the separation layer 15 and the substrate 17 is manufactured, surface irregularities that reflect the distribution of the modified parts 15a and 15b and the cracks 15c included in the separation layer 15 are formed in the newly-exposed surface of the ingot 11. Thus, in the case of manufacturing a new substrate from the ingot 11, it is preferable to planarize the surface of the ingot 11 prior to the separation layer forming step (S1).

This can suppress diffuse reflection of the laser beam LB with which the ingot 11 is irradiated in the separation layer forming step (S1) at the surface of the ingot 11. Similarly, in the present invention, the surface on the side of the separation layer 15 in the substrate 17 split off from the ingot 11 may be planarized by grinding or polishing.

Further, the ingot used for manufacturing a substrate in the present invention is not limited to the ingot 11 illustrated in FIG. 1, FIG. 2, and so forth. Specifically, in the present invention, a substrate may be manufactured from an ingot composed of single-crystal silicon in which a crystal plane that is not included in the crystal planes {100} is exposed in each of a front surface and a back surface.

Moreover, in the present invention, a substrate may be manufactured from a circular columnar ingot in which a notch is formed in a side surface. Alternatively, in the present invention, a substrate may be manufactured from a circular columnar ingot in which neither an orientation flat nor a notch is formed in a side surface. In addition, in the present invention, a substrate may be manufactured from a circular columnar ingot composed of a semiconductor material other than single-crystal silicon, such as single-crystal silicon carbide.

Further, in the present invention, a bare wafer composed of a semiconductor material may be employed as a workpiece to manufacture a substrate. This bare wafer has a thickness that is at least two times and at most five times of that of the substrate to be manufactured, for example.

Moreover, this bare wafer is manufactured by being split off from the ingot 11 by a method similar to the above-described method, for example. In this case, it is also possible to represent that the substrate is manufactured by repeating the above-described method twice.

Further, in the present invention, a device wafer manufactured by forming semiconductor devices on one surface of this bare wafer may be employed as a workpiece to manufacture a substrate. In this case, it is preferable that the device wafer be irradiated with the laser beam LB from the side on which the semiconductor devices are not formed in the device wafer, in order to prevent an adverse effect on the semiconductor devices.

Besides, structures, methods, and so forth according to the above-described embodiment can be carried out with appropriate changes without departing from the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A manufacturing method of a substrate by which the substrate is manufactured from a workpiece having a first surface and a second surface on an opposite side of the first surface, the manufacturing method comprising:
a separation layer forming step of forming a separation layer including modified parts and cracks that extend from the modified parts, inside the workpiece, by irradiating the workpiece with a laser beam with such a wavelength as to be transmitted through a material that configures the workpiece from a side of the first surface; and
a splitting-off step of splitting off the substrate from the workpiece with use of the separation layer as a point of origin, after the separation layer forming step is executed, wherein
the separation layer forming step includes
a preliminary processing step of forming the modified parts in an outer circumferential region of the workpiece by moving focal points on which the laser beam is focused and the workpiece relative to each other in a state in which the focal points are positioned to the outer circumferential region, and
a main processing step of, after the preliminary processing step is executed, forming the modified parts and the cracks in each of multiple linear regions that each extend along a first direction and are included in the workpiece, by repeating a laser beam irradiation step of moving the focal points and the workpiece relative to each other along the first direction in a state in which the focal points are positioned to any of the multiple linear regions and an indexing feed step of moving a position at which the focal points are formed and the workpiece relative to each other along a second direction that is orthogonal to the first direction and is parallel to the first surface.

2. The manufacturing method of a substrate according to claim 1, wherein
the focal points are positioned to a first depth from the first surface in the preliminary processing step, and
the focal points are positioned to a second depth different from the first depth from the first surface in the laser beam irradiation step.

3. The manufacturing method of a substrate according to claim 1, wherein
power of the laser beam focused on the focal points in the preliminary processing step is lower than power of the laser beam focused on the focal points in the laser beam irradiation step.

4. The manufacturing method of a substrate according to claim 1, wherein
the workpiece is composed of single-crystal silicon manufactured in such a manner that a specific crystal plane included in crystal planes {100} is exposed in each of the first surface and the second surface, and
the first direction is parallel to the specific crystal plane, and an angle formed by the first direction and a specific crystal orientation included in crystal orientations <100> is equal to or smaller than 5°.

5. The manufacturing method of a substrate according to claim 2, wherein
power of the laser beam focused on the focal points in the preliminary processing step is lower than power of the laser beam focused on the focal points in the laser beam irradiation step.

6. The manufacturing method of a substrate according to claim 2, wherein
the workpiece is composed of single-crystal silicon manufactured in such a manner that a specific crystal plane included in crystal planes {100} is exposed in each of the first surface and the second surface, and
the first direction is parallel to the specific crystal plane, and an angle formed by the first direction and a specific crystal orientation included in crystal orientations <100> is equal to or smaller than 5°.

7. The manufacturing method of a substrate according to claim 3, wherein
the workpiece is composed of single-crystal silicon manufactured in such a manner that a specific crystal plane included in crystal planes {100} is exposed in each of the first surface and the second surface, and
the first direction is parallel to the specific crystal plane, and an angle formed by the first direction and a specific crystal orientation included in crystal orientations <100> is equal to or smaller than 5°.
